(19) United States
(12) Patent Application Publication
(10) Pub. No.: US 2007/0139037 A1
(43) Pub. Date: Jun. 21, 2007

(54) Device for Testing Magnetic Speed and Proximity Sensors Used with Rotating Machinery

(75) Inventor: Richard Daigre, Hopkinsville, KY (US)

Correspondence Address: WADDEY & PATTERSON, P.C., 1600 DIVISION STREET, SUITE 500, NASHVILLE, TN, 37203, US

(73) Assignee: WHITE DRIVE PRODUCTS, INC, Hopkinsville, KY (US)

(21) Appl. No.: 11/678,390

(22) Filed: Feb. 23, 2007

Related U.S. Application Data
(62) Division of application No. 11/009,850, filed on Nov. 12, 2004.
(60) Provisional application No. 60/519,362, filed on Nov. 12, 2003.

(51) Int. Cl. G01R 35/00

(52) U.S. Cl. 324/202

(57) ABSTRACT

A testing device for testing Hall-Effect type speed and proximity sensors and their associated pulse detection systems is provided by the present invention. The device includes a housing containing an internal battery, an LED display, an input connector, an output cable, a power switch, a test function switch, and a built in reference magnetic label. The magnetic label is polarized with a reference pattern such as alternating north and south magnetic poles. To test a Hall-Effect sensor, the sensor output is connected to the testing device and the sensor is swiped along the magnetic strip. The output of the sensor is then displayed such that it can be examined to determine if the sensor is working properly. A pulse generator is included that produces a known pulse train that is used to evaluate an associated pulse detection circuit. The output of the pulse detection circuit in response to the reference pulse train is examined to determine if the pulse detection circuit is functioning properly.

### CROSS-REFERENCES TO RELATED APPLICATIONS

This application is a Divisional Application of co-pending U.S. patent application Ser. No. 11/009,850, filed Nov. 12, 2004, entitled “Device for Testing Magnetic Speed and Proximity Sensors Used with Rotating Machinery”, which claims benefit of U.S. Patent Application Ser. No. 60/519,362, filed Nov. 12, 2003, entitled “Device for Testing Magnetic Speed and Proximity Sensors Used with Rotating Machinery”, both of which are hereby incorporated by reference.

### STATEMENT REGARDING FEDERALLY SPONSORED RESEARCH OR DEVELOPMENT

Not Applicable

### REFERENCE TO SEQUENCE LISTING OR COMPUTER PROGRAM LISTING APPENDIX

Not Applicable

### FIELD OF THE INVENTION

The present invention relates generally to devices used to test the operation of speed sensors, proximity sensors, and pulse detectors associated with rotating machinery. More particularly, the present invention pertains to a stand-alone device for confirming the proper operation of magnetic-type speed and proximity sensors and pulse detection circuits that are used in the operation and control of hydraulic motors and other rotating machinery.

### BACKGROUND OF THE INVENTION

In many applications of hydraulic motors and other rotating machinery, the motor is part of an automated or closed-loop feedback and control system where it is essential for the system to “know” the speed of the motor at various intervals or points in time. Conventionally, Hall-effect and other magnetic type proximity sensors are used to sense rotation, movement, or dynamic position of a component of the machinery and output a corresponding electrical signal such as a pulse train that is representative of the speed or position. The pulse train output is often provided to a pulse detection circuit that determines the speed or position based upon a predetermined relationship between the pulse train output from the sensor and the speed or position of the machinery as part of the automation or motor control system.

Manufacturers and end-users of motors and motor control systems frequently have a need to quickly confirm that magnetic speed and proximity sensors are working properly and that the associated pulse detection circuits that receive the output signals from such sensors are operating properly. Although it is possible to build testing circuits into the equipment itself, to do so can unnecessarily and substantially add to the cost of the motor or control system and is an inefficient use of the testing equipment. Therefore, what is needed is a low cost, easy to use, portable, stand-alone device that can quickly confirm the proper operation of critical sensor components of a motor speed control system.

### BRIEF SUMMARY OF THE INVENTION

A preferred embodiment of the present invention is directed toward a sensor testing device for testing Hall-Effect type speed and proximity sensors and pulse detection circuits associated with the use of hydraulic motors and other rotating machinery. The preferred sensor testing device includes a tester housing containing an internal battery, an LED display, an input connector, an output cable, a power switch, a test function switch, and a built in reference magnetic label, which is polarized with alternating north and south magnetic poles. To test a Hall-Effect sensor, the sensor is connected to the output cable, the “Sensor” function is selected and the sensor is “swiped” along the label/magnetic strip. If the sensor is working properly, the user will receive a visual signal from a flashing LED on the tester and/or an audible signal such as a beep from an internal audio signal generator that indicates that this is the case.

The preferred sensor testing device can be also used as a stand-alone device to check the operation of the end user's pulse detection circuit. The input cable of the end user's pulse detection circuit is disconnected from the speed sensor and connected to the input connector on the sensor tester. When the testing device is connected to the pulse detection system and the “System” function is selected, the sensor tester will output pulses at a constant rate corresponding to a constant speed thereby simulating an operational speed sensor. The sensor testing device provides visual and/or audible outputs that indicate the status of the test. The end user can verify that the pulse detection circuit is functioning properly by checking to see if the pulse detection circuit is displaying a reading corresponding to the pulses output by the sensor testing device.

Sensors and pulse detection circuits may be tested individually or together by connected the testing device inline between the sensor and the pulse detection circuit.

The sensor testing device's LED display preferably indicates the selected function and operation of the sensor testing device. The device also has an output LED that lets the user know if the system cable is supplying power to the tester. If external power is being supplied to the testing device, the supplied power is used to operate the testing device during long trouble-shooting processes which could otherwise drain the internal battery. In addition, when using externally supplied system power, the sensor testing device activates an internal recharging circuit that charges the internal battery in order to increase battery life.

### BRIEF DESCRIPTION OF THE SEVERAL VIEWS OF THE DRAWINGS

FIG. 1 is a schematic diagram of a sensor testing device constructed in accordance with a preferred embodiment of the present invention; and

FIG. 2 is a pictorial representation of a sensor testing device constructed in accordance with a preferred embodiment of the present invention.

### DETAILED DESCRIPTION OF THE INVENTION

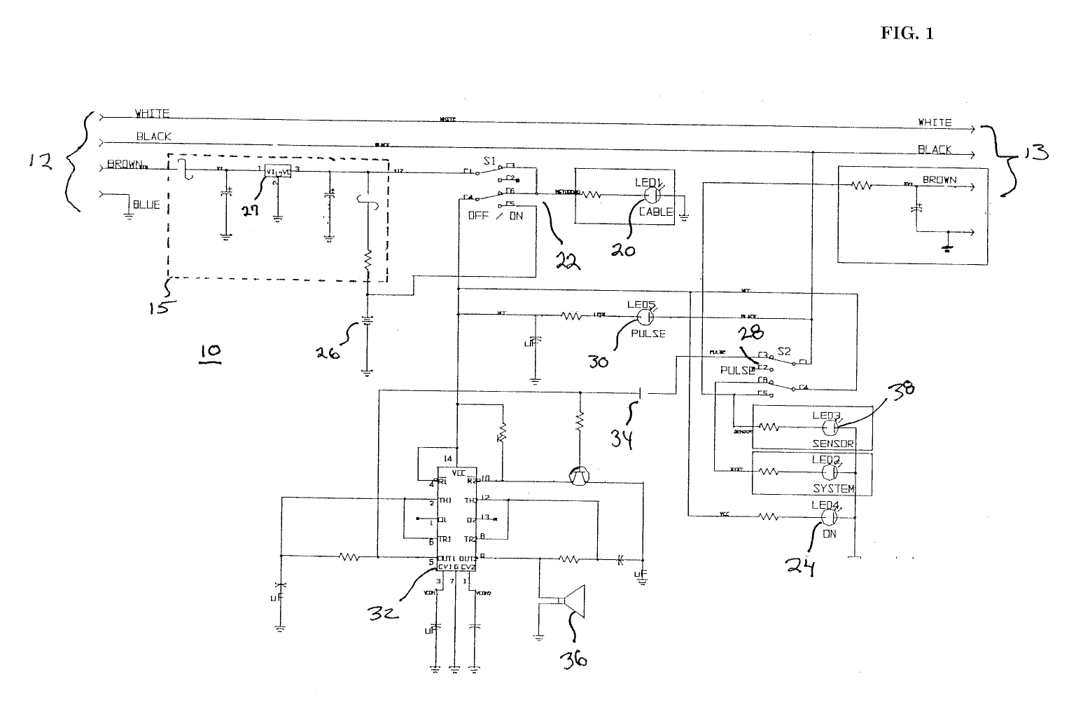

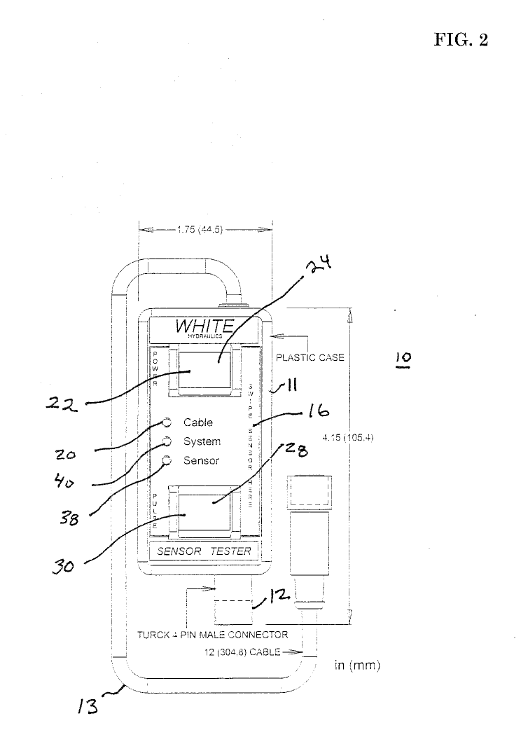

Referring now to FIGS. 1 and 2, a preferred embodiment of the sensor testing device 10 of the present invention is shown in schematic and pictorial form. The device 10 is preferably configured for stand-alone operation with all of the components mounted in, or attached to, a portable housing 11. The portable housing 11 is shaped and sized to conveniently fit into the pocket of standard work pants. This is important in that the device 10 can easily be carried along with other test equipment along a route of machines to be inspected or tested. The portable nature of the testing device 10 is further beneficial in that it allows a user to quickly and easily test sensors mounted on multiple machines in various locations that may not have electrical power readily available. Most preferably, the housing 11 is constructed from flame resistant ABS plastic due to its durability and ease of use.

The portable housing 11 has a number of inputs and outputs for receiving and transmitting signals. For example, an input connector 12 is positioned on the housing 11 that is adapted to receive a pulse detection circuit output cable such as is typically used to connect a Hall-Effect type speed sensor to a pulse detection circuit. Most preferably, the input connector 12 is a Turck 4-pin male connector. If the cable connected to the input connector 12 is providing power to the testing device 10, the cable light emitting diode 20 will be illuminated. The connector 12 allows the device 10 to send a pulse train to a pulse detection circuit.

An output cable 13, sometimes referred to as a pigtail, is also positioned on the housing 11 that is adapted to be connected directly to the output of a Hall-Effect type sensor that is to be tested. The output cable 13 allows the testing device 10 to receive the output of a sensor such that the device 10 can examine the sensor output to insure that it is functioning properly. A most preferred output cable 13 is a 12-inch 3 or 4 pin female connector. While the embodiment of FIGS. 1 and 2 is directed toward testing a Hall-Effect sensor, it will be readily appreciated by those skilled in the art that the present invention could also be used to test any magnetic or optical sensors.

The operation of the device 10 is preferably controlled through the use of two switches. Power switch 22 is used to switch power to the device 10 on and off. The powered status of the device 10 is indicated by light emitting diode 24 which is integrated with the power switch 22. Operating power for the device 10 can be obtained from a power cable attached to input connector 12 using an internal power supply circuit 15 that may include an integrated circuit 27 for voltage regulation. In addition, the output of the power supply circuit 15 may be used to charge an internal battery 26, which is preferably a 12 volt alkaline battery, when external power is available.

Function switch 28, also referred to as the pulse button, switches the device 10 between a “Sensor” testing mode, wherein the output of a sensor is monitored, to a “System” testing mode, wherein a pulse detection circuit is tested. If the System mode is selected, light emitting diode 40 will be illuminated to indicate to a user that the device 10 is in the System mode. The Sensor testing mode is selected by placing the function switch 28 in the Sensor position. When the Sensor mode is selected, light emitting diode 38 will be illuminated to indicate that the device is in the Sensor mode.

Sensors and pulse detection circuits may be tested individually by connecting them to the testing device one at a time, or together by connecting the testing device 10 inline between the pulse detection circuit and the sensor. To test a sensor, the testing device's output cable 13 is connected to the sensor output. If the sensor is to be tested inline in conjunction with a pulse detection circuit, the input connector 12 is connected to the input of the pulse detection circuit. Once the necessary connections have been made and the Sensor mode selected, the sensor is swiped along the magnetic label 16. A light emitting diode 30, also referred to as the pulse light, is preferably positioned behind function switch 28 so that it can be viewed through the surface of the switch 28. If the pulse light 30 flashes as the sensor is moved across the magnetic label 16, the sensor being tested is working properly. The audio transducer 36 preferably beeps or clicks whenever the pulse light flashes to provide an additional indication of the sensors functioning. This is easily accomplished by using the same triggering signal for the audio transducer 36 as the pulse light 30. Alternatively, a separate controller can be used to generate the signals for the audio transducer 36 such that any desired sound can be produced to indicate the results of the tests.

To test a pulse detection circuit, the System testing mode is selected by placing the function switch 28 in the “System” position. Like a Sensor mode test, a System mode test can be performed with just the pulse detection circuit connected to the testing device 10 or with the testing device 10 connected inline between the sensor and the pulse detection circuit. In either case, the pulse detection circuit's input is connected to the input connector 12. The light emitting diode 30 that is integral with the function switch 28 visually indicates that the pulse detector circuit testing mode is active by flashing. The rate of flashing may correspond to the rate of pulsing, i.e. a certain number of pulses for each flash, or be independent of the pulsing, i.e. a certain number of flashes per second. An integrated circuit 32 is provided that contains a conventional timing circuit configured to generate a simulated speed sensor pulse train that is sent to the pulse detection circuit through a high speed diode 34 and the input connector 12. The same timing circuit, or alternatively another timing circuit in integrated circuit 32, is preferably configured as an audio signal generator and connected to audio transducer 36 to generate audible outputs that correspond to the pulsing of the pulse light 30. If the pulse detection circuit is functioning properly, it will show a simulated sensor pulse rate that approximately corresponds to the pulses provided from the testing device 10. A protection circuit may be provided to prevent damage to the device 10 due to short circuits or harmful voltages on the input connector 12 and output cable 13.

The reference magnetic strip or label 16 is preferably provided on the surface of the device housing 11 for use in testing a Hall-Effect type sensor as shown in FIG. 2. Although a variety of magnetic patterns could be constructed on the strip 16, an alternating north-south polarized magnetization is preferred due to its ease of construction and verification and its similarity to the rotary magnets typically used in speed sensors. In the Sensor testing mode, the output from the sensor to be tested is connected to output cable 13 as described above. The sensor is then passed over the reference magnetic label 16. If the sensor is working properly, a Hall-Effect voltage will be induced in the sensor when it is exposed to the magnetic field proximate to magnetic label 16 that corresponds to the polarization pattern of the magnetic label 16. This voltage signal is provided to the device 10 through cable 13. If the sensor is functioning properly, the induced voltage will cause the pulse light 30 to pulse. Thus, in the preferred embodiment, any detected voltage that results in the illumination of the pulse light 30 will indicate a properly functioning sensor. However, in an alternative embodiment, the induced voltage signal can be compared to a reference voltage signal to determine whether the induced voltage signal is varying in a manner that corresponds to the reference magnetic pattern on the magnetic label 16. In such an embodiment, the integrated circuit 32 may be used to perform the comparison. In either case, the presence of an appropriate voltage signal will cause the illumination of light emitting diode 30 and the generation of a corresponding audible signal by audio transducer 36 which indicates that the sensor being tested is properly functioning. If the pulse light 30 does not pulse in response to the sensor being swiped along the magnetic label 16, the sensor is malfunctioning.

In the System testing mode, the integrated circuit 32 generates a pulse train that simulates the output of a speed sensor. The pulse light 30 pulses in accordance with the generated pulses to provide a user an indication that the device 10 is functioning properly. The device 10 provides the generated reference pulse train to the pulse detector circuit being evaluated through connector 12. If the connector 12 is connected to the sensor input of the pulse detection circuit, and the pulse detector circuit is working properly, a speed indication approximately corresponding to the input reference pulse train should be visible at the output of the pulse detector circuit. The actual speed indication may or may not be accurate and will depend on the voltage levels and pulse geometry used as well as the type of pulse detection circuit being evaluated. If the pulse detection circuit does not produce a speed indication in response to the pulse train, the pulse detection circuit is malfunctioning.

Preferably, the front label on the device housing 11 will also include reference reflective material that can be used to test photoelectric “Mini-Beam” retro reflective sensors. Accordingly, the magnetic test label or strip 16 will include alternating dark and light bars located proximate the magnetic poles. The bars will produce an optical “interrupt” in the output of reflective-type optical sensors similar to that created by the alternating magnetic polarities. By looking for variations in the sensor's output or comparing the output signal of the reflective sensor to the known optical pattern, it can be determined if the optical sensor is functioning properly in a manner similar to that described above for the magnetic sensor.

The device 10 is preferably powered by the internal battery 26. In addition, for extended troubleshooting, the device 10 is also capable of operating off of power provided through a cable connected to input 13 while also trickle-charging the internal battery 26.

Although operation of the device 10 has been primarily described with respect to testing of Hall-Effect type sensors used with rotating machinery, it will be recognized by those of skill in the art that the device 10 can be used to confirm the basic operation of other magnetic-type speed and proximity sensors.

Thus, although there have been described particular embodiments of the present invention of a new and useful Device for Testing Magnetic Speed and Proximity Sensors Used with Rotating Machinery, it is not intended that such references be construed as limitations upon the scope of this invention except as set forth in the following claims.

What is claimed is:

1. A testing device for testing a Hall-Effect type sensor, said testing device comprising;
an input for connecting said testing device to an output of a Hall-Effect sensor;
a magnetic label having a magnetic pattern wherein said Hall-Effect is scanned across said magnetic label and said output of said Hall-Effect sensor is examined to determine if said Hall-Effect sensor is properly functioning; and
a reference reflective structure such that an optical sensor can be tested in a manner similar to said magnetic sensor.

2. The testing device of claim 1 further comprising a pulse detection circuit testing device having a pulse generator for providing pulses to a pulse detection circuit at a constant rate to simulate an operational speed sensor such that a user of said testing device can monitor the pulse detection circuit's response to said pulses to see if it is correctly detecting the provided pulses.

3. The testing device of claim 2 further comprising a function selection switch for selecting between the pulse detection circuit testing function and the Hall-Effect sensor testing function.

4. The testing device of claim 1 wherein said magnetic label is polarized with alternating north and south magnetic poles.

5. The testing device of claim 1 further comprising an LED display for communicating results of said testing to a user.

6. The testing device of claim 1 further comprising a battery and a system power input wherein said battery supplies power for said testing device when an external power source is not connected to said system power input and said battery is charged when an external power source is connected to said system power input.

7. A testing device for testing a magnetic sensor, said testing device comprising:
an input for receiving the output of a magnetic sensor;
a reference magnetic structure having a predetermined magnetic pattern wherein said magnetic sensor is tested by scanning said reference magnetic structure with said magnetic sensor and examining the sensor's output; and
a reference reflective structure such that an optical sensor can be tested in a manner similar to said magnetic sensor.

8. The device of claim 7 wherein said device is contained in a portable housing having a display for displaying the sensor's output.

9. The device of claim 7 further comprising a pulse generator for generating a predetermined pulse sequence and a pulse output for providing said predetermined pulse sequence to a pulse detection circuit such that said pulse detection circuit's performance in response to a known stimuli can be monitored.

10. The device of claim 9 further comprising a function selection switch for selecting between said magnetic sensor testing function and said pulse detection circuit testing function.

11. The device of claim 7 further comprising a battery and a power input wherein said battery provides power to said device when no external power source is connected to said power input and wherein said battery is charged when an external power source is connected to said power input.

12. The device of claim 7 wherein said reference magnetic structure comprises a magnetic label having a series of alternating polarity magnetic poles.

13. The device of claim 7 further comprising a microprocessor for controlling said testing device.

14. A testing device for testing a Hall-Effect type sensor, said testing device comprising;
a housing;
an input coupled to the housing for connecting said testing device to an output of a Hall-Effect sensor;
a magnetic label applied to the housing, the label having a magnetic pattern wherein said Hall-Effect is scanned across said magnetic label and said output of said Hall-Effect sensor is examined to determine if said Hall-Effect sensor is properly functioning; and
a reference reflective structure such that an optical sensor can be tested in a manner similar to said magnetic sensor.

15. The testing device of claim 14 further comprising a pulse detection circuit testing device having a pulse generator for providing pulses to a pulse detection circuit at a constant rate to simulate an operational speed sensor such that a user of said testing device can monitor the pulse detection circuit's response to said pulses to see if it is correctly detecting the provided pulses.

16. The testing device of claim 15 further comprising a function selection switch for selecting between the pulse detection circuit testing function and the Hall-Effect sensor testing function.

17. The testing device of claim 14 wherein said magnetic label is polarized with alternating north and south magnetic poles.

18. The testing device of claim 14 further comprising an LED display for communicating results of said testing to a user.

19. The testing device of claim 14 further comprising a battery and a system power input wherein said battery supplies power for said testing device when an external power source is not connected to said system power input and said battery is charged when an external power source is connected to said system power input.
